(19) United States
(12) Patent Application Publication
(10) Pub. No.: US 2024/0268235 A1
(43) Pub. Date: Aug. 8, 2024

(54) PIEZOELECTRIC ELEMENT AND DISK DRIVE SUSPENSION

(71) Applicant: NHK SPRING CO., LTD., Yokohama-shi (JP)

(72) Inventors: Mikio ARAI, Yokohama-shi (JP); Ryosuke YONEKURA, Yokohama-shi (JP)

(73) Assignee: NHK SPRING CO., LTD., Yokohama-shi (JP)

(21) Appl. No.: 18/408,598

(22) Filed: Jan. 10, 2024

(30) Foreign Application Priority Data
Feb. 7, 2023 (JP) 2023-016907

(51) Int. Cl. H10N 30/87; G11B 25/04; H10N 30/50

(52) U.S. Cl. CPC H10N 30/87; G11B 25/043; H10N 30/508

(57) ABSTRACT

According to one embodiment, a piezoelectric element includes a piezoelectric body having a first main surface and a second main surface located on a side opposite to the first main surface, a first electrode provided on the first main surface, and a second electrode provided on the second main surface. The first electrode includes a first peripheral edge and a first slit extending from the first peripheral edge. An end portion of the first slit is separated from the first peripheral edge.

### CROSS-REFERENCE TO RELATED APPLICATIONS

This application is based upon and claims the benefit of priority from prior Japanese Patent Application No. 2023-016907, filed Feb. 7, 2023, the entire contents of which are incorporated herein by reference.

### BACKGROUND OF THE INVENTION

### 1. Field of the Invention

The present invention relates to a piezoelectric element and a disk drive suspension.

### 2. Description of the Related Art

A hard disk drive (HDD) is used in an information processing apparatus such as a personal computer. The hard disk drive includes a magnetic disk which rotates about a spindle, a carriage which turns about a pivot, and the like. The carriage comprises an arm, and turns in a disk track width direction about the pivot by a positioning motor such as a voice coil motor.

A disk drive suspension (hereinafter simply referred to as a suspension) is attached to the above arm. The suspension includes a load beam, a flexure stacked on the load beam, and the like. A slider which constitutes a magnetic head is provided on a gimbal portion formed near a distal end of the flexure.

An element (transducer) for accessing data such as reading or writing data is provided on the slider. A head gimbal assembly is constituted by the load beam, the flexure, the slider, and the like.

In order to support higher recording density on disks, it is necessary to further miniaturize the head gimbal assembly and to enable the slider to be positioned on the recording surface of the disk with higher accuracy.

A dual stage actuator (DSA) suspension that combines a positioning motor (voice coil motor) and an actuator mounted on the base plate side, and a triple stage actuator (TSA) suspension that has an actuator mounted on the magnetic head side, and the like, for the purpose of improving the positioning accuracy of the magnetic head, are known.

A piezoelectric element used as the actuator is also becoming smaller and thinner. Cracks may occur in such a piezoelectric element during the manufacturing process. For this reason, various proposals for inspection of piezoelectric elements have been made (for example, JP 4655504 B, JP 6506707 B, JP 5489968 B, and JP 5268762 B).

Even if the above-mentioned patent documents are considered, there is still room for various improvements in detecting cracks which occur in piezoelectric elements.

### BRIEF SUMMARY OF THE INVENTION

Embodiments described herein aim to provide a piezoelectric element and a disk drive suspension capable of easily detecting cracks.

In general, according to one embodiment, a piezoelectric element comprises a piezoelectric body having a first main surface and a second main surface located on a side opposite to the first main surface, a first electrode provided on the first main surface, and a second electrode provided on the second main surface. The first electrode includes a first peripheral edge and a first slit extending from the first peripheral edge. An end portion of the first slit is separated from the first peripheral edge.

A plurality of first slits may be provided along the first peripheral edge. The first peripheral edge may include a first edge portion extending in a first direction, and a second edge portion extending in the first direction and aligned with the first edge portion in a second direction that intersects the first direction. The first slits extending from the first edge portion may be spaced apart from the first slits extending from the second edge portion, in the second direction.

The first peripheral edge may include a first edge portion extending in a first direction, and a second edge portion extending in the first direction and aligned with the first edge portion in a second direction that intersects the first direction. The first slits extending from the first edge portion may be spaced apart from and arranged alternately with the first slits extending from the second edge portion, in the second direction.

The first slit may have a spiral shape. The first slit may include a first slit portion extending from the first peripheral edge, and a pair of second slit portions connected to the first slit portion. The first slit portion may be located between the pair of second slit portions. The pair of second slit portions may extend along the first slit portion. Each of end portions of the pair of second slit portions may be separated from the first peripheral edge.

According to another embodiment, a piezoelectric element comprises a piezoelectric body having a first main surface and a second main surface located on a side opposite to the first main surface, a first electrode provided on the first main surface, and a second electrode provided on the second main surface. The first electrode includes a first peripheral edge and a first slit extending from the first peripheral edge. The second electrode includes a second peripheral edge and a second slit extending from the second peripheral edge. An end portion of the first slit is separated from the first peripheral edge. An end portion of the first slit is separated from the first peripheral edge. According to yet another embodiment, a disk drive suspension comprises the piezoelectric element.

According to the piezoelectric element and the disk drive suspension comprising the above-described configuration, cracks can easily be detected.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic perspective view showing an example of a disk drive.

FIG. 2 is a schematic cross-sectional view showing a part of the disk drive.

FIG. 3 is a schematic plan view showing a suspension according to the first embodiment.

FIG. 4 is a schematic perspective view showing a piezoelectric element provided in the suspension according to the first embodiment.

FIG. 5 is a schematic plan view showing the piezoelectric element shown in FIG. 4.

FIG. 6 is a view schematically showing the piezoelectric element and an inspection device.

FIG. 7 is a flowchart showing an example of a process of inspecting the piezoelectric element by the inspection device.

FIG. 8 is a schematic perspective view showing the piezoelectric element according to a comparative example.

FIG. 9 is a view illustrating a state in which a crack occurs in the piezoelectric element according to the comparative example.

FIG. 10 is a view illustrating a state in which a crack occurs in the piezoelectric element according to the first embodiment.

FIG. 11 is a schematic plan view showing an electrode in a second embodiment.

FIG. 12 is a schematic plan view showing an electrode in a third embodiment.

FIG. 13 is a schematic plan view showing an electrode in a fourth embodiment.

FIG. 14 is a schematic plan view showing an electrode in a fifth embodiment.

FIG. 15 is a schematic plan view showing an electrode in a sixth embodiment.

### DETAILED DESCRIPTION OF THE INVENTION

Each of embodiments of the invention will be described hereinafter with reference to the accompanying drawings. In order to make the description clearer, the sizes, shapes and the like of the respective parts may be changed and illustrated schematically in the drawings as compared with those in an accurate representation.

In the figures, an X-axis, a Y-axis and a Z-axis orthogonal to each other are described to facilitate understanding as needed. A direction along the X-axis is referred to as a direction X, a direction along the Y-axis is referred to as a direction Y, and a direction along the Z-axis is referred to as a direction Z. In addition, the direction Z may also be referred to as an upper or upward direction, and the direction opposite to the direction Z may be referred to as a lower or downward direction. The direction Z is a normal to a plane including the direction X and the direction Y. Viewing various elements parallel to the direction Z is referred to as plan view. In each of the following embodiments, the direction X corresponds to an example of a first direction, and the direction Y corresponds to an example of a second direction.

### First Embodiment

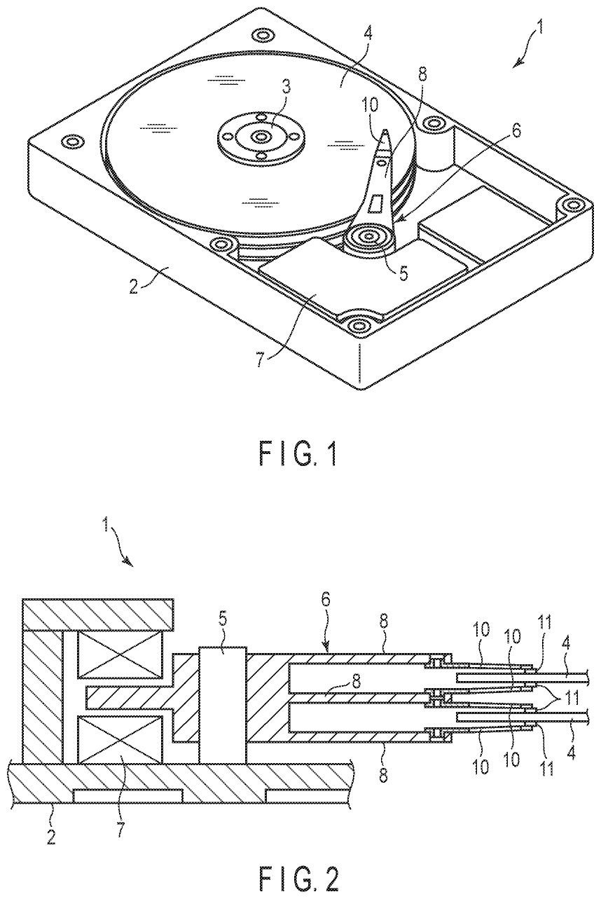

FIG. 1 is a schematic perspective view showing an example of a disk drive (HDD) 1. In the example shown in FIG. 1, the disk drive 1 comprises a casing 2, a plurality of magnetic disks (hereafter simply referred to as disks 4) rotating around a spindle 3, a carriage 6 which can rotate around a pivot 5, and a positioning motor (voice coil motor) 7 for driving the carriage 6. The casing 2 is sealed by a lid (not shown).

FIG. 2 is a schematic cross-sectional view showing a part of the disk drive 1. The carriage 6 is provided with a plurality of (for example, three) arms 8 as shown in FIG. 1 and FIG. 2. A suspension 10 is attached to each of distal portions of the plurality of arms 8. A slider 11, which constitutes the magnetic head, is provided on the distal portion of the suspension 10. When the disk 4 rotates at a high speed, air flows in between the disk 4 and the slider 11, and an air bearing is thereby formed.

When the carriage 6 is turned by the positioning motor 7, the suspension 10 moves in the radial direction of the disk 4, and the slider 11 thereby moves to a desired track of the disk 4. For example, an element capable of converting magnetic and electrical signals, such as an MR element, is provided at the distal portion of the slider 11. Accessing data such as writing data to or reading data from the disk 4 is performed by the element.

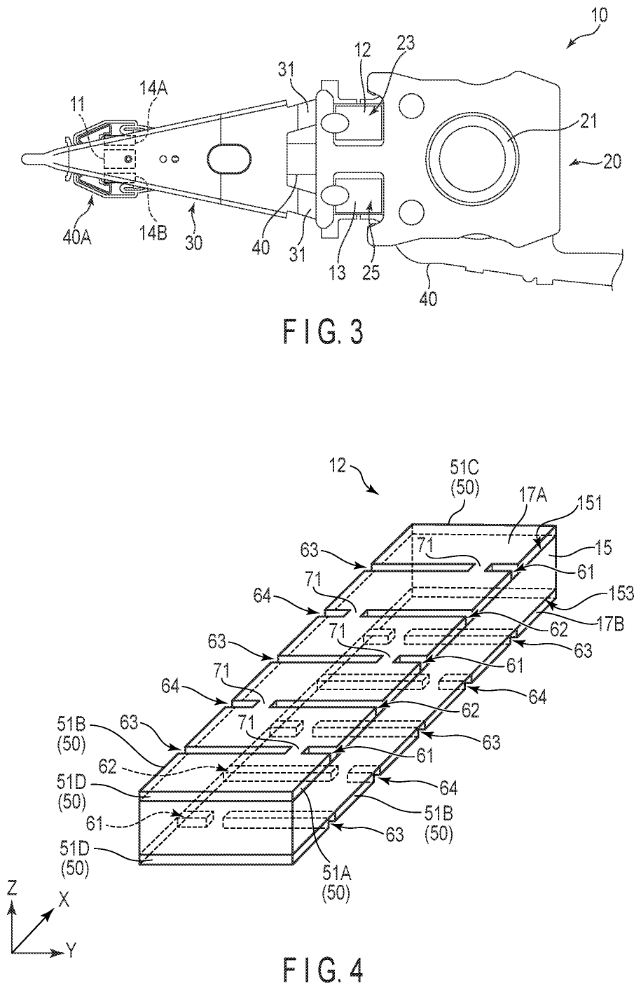

FIG. 3 is a schematic plan view showing the suspension 10 according to the present embodiment. In the present embodiment, a TSA type suspension is disclosed as an example of the suspension 10. The suspension 10 comprises a base plate 20, a load beam 30, and a flexure 40.

The base plate 20 is connected to the arm 8 (shown in FIG. 2). The base plate 20 is formed of, for example, a metallic material such as stainless steel. The base plate 20 includes a boss portion 21. The base plate 20 is attached to the arm 8 via the boss portion 21.

The load beam 30 is formed of a metallic material such as stainless steel. The load beam 30 is tapered toward the distal end (left side in FIG. 3).

The load beam 30 is elastically supported by the base plate 20 via a spring portion 31. The load beam 30 is fixed to the base plate 20 by, for example, spot welding using a laser.

The flexure 40 is arranged along the base plate 20 and the load beam 30. The flexure 40 is fixed to the base plate 20 and the load beam 30 by, for example, spot welding using a laser. The flexure 40 includes a portion extending to a rear side of the base plate 20 (right side in FIG. 3).

The flexure 40 includes a metal base (not shown) formed of, for example, a thin stainless steel plate and a wiring portion (not shown) stacked on the metal base. A slider 11 constituting the magnetic head is provided at a distal portion 40A of the flexure 40.

The suspension 10 further comprises piezoelectric elements 12 and 13, and a pair of piezoelectric elements 14A and 14B arranged on both sides of the slider 11. The piezoelectric elements 14A and 14B may be mounted on, for example, a surface on a side opposite to the surface on which the slider 11 is mounted on the flexure 40. The piezoelectric elements 12 and 13 are accommodated in apertures 23 and 25, respectively.

The apertures 23 and 25 are defined by, for example, the base plate 20, the load beam 30, and the like. An actuator mount portion is formed by the apertures 23 and 25. The apertures 23 and 25 are aligned in the width direction of the suspension 10 as shown in FIG. 3. The piezoelectric elements 12 and 13 are fixed to the apertures 23 and 25 by an adhesive material. The adhesive material is, for example, an electrically insulating resin adhesive such as epoxy resin.

An example of the structures of the piezoelectric elements 12 and 13 will be described using the piezoelectric element 12. For example, the piezoelectric element 13 has the same structure as the piezoelectric element 12.

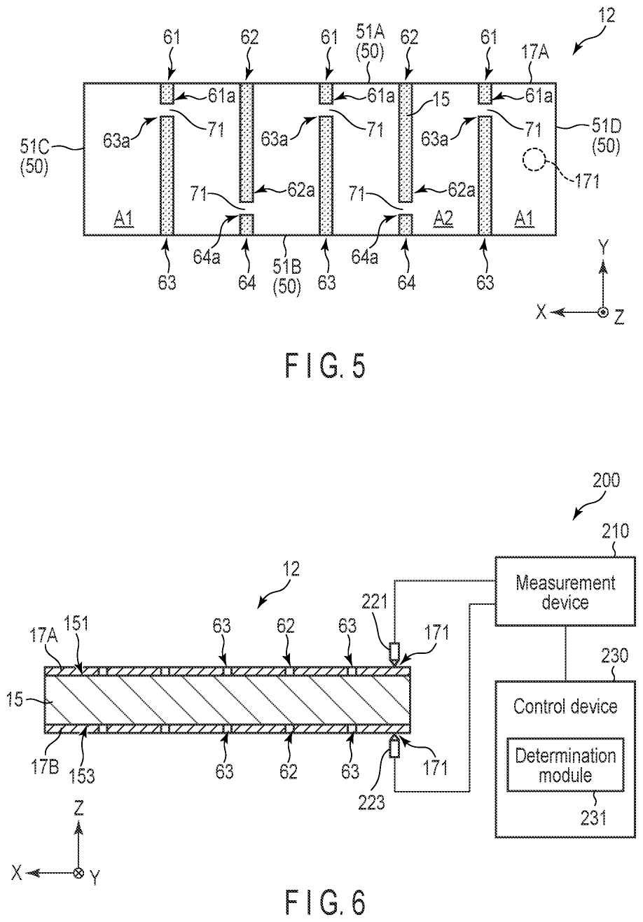

FIG. 4 is a schematic perspective view showing the piezoelectric element 12 provided on the suspension 10 according to the present embodiment. FIG. 5 is a schematic plan view showing the piezoelectric element 12 shown in FIG. 4. In FIG. 5, the piezoelectric element 12 is viewed in a direction opposite to the direction Z.

The piezoelectric element 12 comprises a piezoelectric body 15 and electrodes 17A and 17B as shown in FIG. 4. In the present embodiment, the electrode 17A corresponds to an example of a first electrode and the electrode 17B corresponds to an example of a second electrode.

The piezoelectric body 15 extends and contracts by the piezoelectric effect when a voltage is applied. The piezoelectric body 15 is formed of, for example, lead zirconate titanate (PZT). The piezoelectric body 15 may be formed of a plurality of layers or a single layer.

The piezoelectric body 15 has, for example, a substantially rectangular shape elongated in the direction X. In other words, the piezoelectric body 15 has a substantially rectangular shape in plan view. Incidentally, the piezoelectric body 15 may have a shape other than the rectangular shape. The piezoelectric body 15 may have, for example, a substantially cubic shape.

The piezoelectric body 15 has a first main surface 151 and a second main surface 153 located on a side opposite to the first main surface 151 in the direction Z. The first main surface 151 and the second main surface 153 are, for example, surfaces parallel to an X-Y plane defined by the direction X and the direction Y. In this case, being parallel also implies being slightly inclined to the X-Y plane.

The electrodes 17A and 17B are formed on a flat surface by, for example, sputtering, plating or the like. The electrodes 17A and 17B are formed of, for example, a metallic material such as gold.

The electrode 17A is provided on the first main surface 151, and the electrode 17B is provided on the second main surface 153. The electrode 17B has, for example, the same shape as the electrode 17A. In the example shown in FIG. 4, the shape of the electrode 17A as viewed in the direction opposite to the direction Z is the same as the shape of the electrode 17B as viewed in the direction Z. Incidentally, the shape of the electrode 17A as viewed in the direction opposite to the direction Z may be the same as the shape of the electrode 17B as viewed in the direction opposite to the direction Z. The electrode 17A will be described below.

The electrode 17A has a substantially rectangular shape in plan view. The electrode 17A has a peripheral edge 50. In the present embodiment, the peripheral edge 50 of the electrode 17A corresponds to an example of the first peripheral edge. The peripheral edge 50 overlaps with, for example, a peripheral edge of the first main surface 151 in the direction Z. In other words, the electrode 17A is formed to cover the entire first main surface 151.

The electrode 17A has a pair of edges 51A and 51B and a pair of edges 51C and 51D. In the present embodiment, the edge 51A corresponds to an example of a first edge and the edge 51B corresponds to an example of a second edge.

The pair of edges 51A and 51B are located on the long sides of the peripheral edge 50 in the examples shown in FIG. 4 and FIG. 5, and the pair of edges 51C and 51D are located on the short sides of the peripheral edge 50. The pair of edges 51A and 51B extend in the direction X and are arranged in the direction Y. The pair of edges 51C and 51D extend in the direction Y and are arranged in the direction X.

The electrode 17A includes a plurality of slits 61 to 64. In the present embodiment, the slits 61 to 64 correspond to examples of the first slits. In FIG. 5, the plurality of slits 61 to 64 are marked with dots.

The plurality of slits 61 to 64 penetrate the electrode 17A in the direction Z. A part of the first main surface 151 is exposed through the plurality of slits 61 to 64. The plurality of slits 61 to 64 are provided along the peripheral edge 50.

More specifically, the plurality of slits 61 and 62 extend from the edge 51A to the edge 51B, and the plurality of slits 63 and 64 extend from the edge 51B to the edge 51A. For example, the plurality of slits 61 to 64 are formed parallel to the Y-axis.

As shown in FIG. 5, the slit 61 includes an end portion 61a, the slit 62 includes an end portion 62a, the slit 63 includes an end portion 63a, and the slit 64 includes an end portion 64a. The end portions 61a to 64a correspond to the end portions separated from the peripheral edge 50.

More specifically, the end portions 61a and 62a are separated from the edge 51B, and the end portions 63a and 64a are separated from the edge 51A. From the other viewpoint, the end portions 61a to 64a of the slits 61 to 64 do not open toward the peripheral edge 50.

A length of the slit 61 in the direction Y is smaller than a length of the slit 62 in the direction Y. A length of the slit 64 in the direction Y is smaller than a length of the slit 63 in the direction Y. For example, the length of the slit 61 in the direction Y is equal to the length of the slit 64 in the direction Y, and the length of the slit 62 in the direction Y is equal to the length of the slit 63 in the direction Y.

The length of the slits 61 and 64 in the direction Y is smaller than, for example, half the length of the electrode 17A in the direction Y. The length of the slits 62 and 63 in the direction Y is larger than, for example, half the length of the electrode 17A in the direction Y. The length (width) of the plurality of slits 61 to 64 in the direction X is desirably smaller.

The slits 61 are spaced apart from and arranged alternately with the slits 62, and the slits 63 are spaced apart from and arranged alternately with the slits 64, in the direction X. For example, the slits 61 and the slits 62 are arranged in the direction X at regular intervals, and the slits 63 and the slits 64 are arranged in the direction X at regular intervals. The slits 61 are spaced apart from the slits 63, and the slits 62 are spaced apart from the slits 64, in the direction Y.

The electrode 17A further includes a plurality of conductive portions 71. The plurality of conductive portions 71 are located between the end portions 61a of the slits 61 and the end portions 63a of the slits 63, and between the end portions 62a of the slits 62 and the end portions 64a of the slits 64, respectively, in the direction Y.

Areas A1 (shown in FIG. 5) between the edges 51C and 51D and the slits 61 and 63 are electrically connected to areas A2 (shown in FIG. 5) between the slits 61 and 63 and the slits 62 and 64 by the conductive portions 71. In this case, being electrically connected means being conductive. Similarly, the areas A2 adjacent in the direction X are electrically connected by the conductive portion 71.

As described above, the electrode 17B has the same shape as the electrode 17A. In the present embodiment, the peripheral edge 50 of the electrode 17B corresponds to an example of a second peripheral edge. The electrode 17B includes a plurality of slits 61 to 64. In the present embodiment, the slits 61 to 64 of the electrode 17B correspond to examples of the second slits. The electrode 17B further includes a plurality of conductive portions.

The electrode 17A includes, for example, a feed connection portion 171 (shown in FIG. 5) in the vicinity of the edge 51D. A position of the feed connection portion 171 is not limited to this example. The feed connection portion 171 of the electrode 17A is electrically connected to, for example, the base plate 20 (shown in FIG. 3), and a feed connection portion of the electrode 17B is electrically connected to, for example, the wiring portion of the flexure 40 (shown in FIG. 3).

Next, an example of an inspection device 200 for inspecting the piezoelectric element 12 will be described.

FIG. 6 is a view schematically showing the piezoelectric element 12 and the inspection device 200. In FIG. 6, the piezoelectric element 12 is shown in cross-section. In FIG. 6, components constituting the suspension 10 other than the piezoelectric element 12 are omitted. The piezoelectric element 12 comprises the piezoelectric body 15 and the electrodes 17A and 17B as described above. The inspection device 200 comprises, for example, a measurement device 210 and a control device 230.

A predetermined voltage is applied between the measurement device 210 and the electrodes 17A and 17B. The measurement device 210 includes, for example, a power supply or the like (not shown). The voltage is, for example, an alternating voltage, but is not limited to this example. For example, the magnitude of the applied voltage is preset.

The measurement device 210 is electrically connected to the feed connection portions 171 of the electrodes 17A and 17B via measurement contacts 221 and 223. For example, the measurement contact 221 is in contact with the electrode 17A, and the measurement contact 223 is in contact with the electrode 17B.

The measurement device 210 further measures the capacitance when the voltage is applied to the piezoelectric element 12. The result of the measurement performed by the measurement device 210 is output to the control device 230.

The control device 230 is communicatively connected to the measurement device 210. The control device 230 is, for example, a combination of semiconductor integrated circuits, electronic components, circuit boards, and the like. The control device 230 includes a storage device (not shown) that stores various data and various programs, and a processor (not shown) that executes these programs.

The control device 230 includes a determination module 231. For example, the processor executes the programs stored in the storage device, and the control device 230 thereby implements a determination module 231 and other functions.

The determination module 231 functions as determination means for determining whether or not the piezoelectric element 12 has a crack. More specifically, the determination module 231 determines whether or not the piezoelectric element 12 has a crack, based on the capacitance measured by the measurement device 210.

The inspection device 200 inspects the piezoelectric elements 12 and 13 using, for example, the suspension 10 on which the piezoelectric elements 12 and 13 are mounted. Incidentally, the measurement contacts 221 and 223 may be in contact with a terminal portion of a tail portion of the flexure 40. The terminal portion is electrically connected to the electrodes 17A and 17B of the piezoelectric elements 12 and 13. In this case, the piezoelectric elements 12 and 13 can also be inspected using the suspension 10 on which the piezoelectric elements 12 and 13 are mounted. However, the inspection device 200 may inspect the piezoelectric elements 12 and 13 before the piezoelectric elements 12 and 13 are mounted.

Next, the process of inspecting the piezoelectric element 12 by the inspection device 200 will be described.

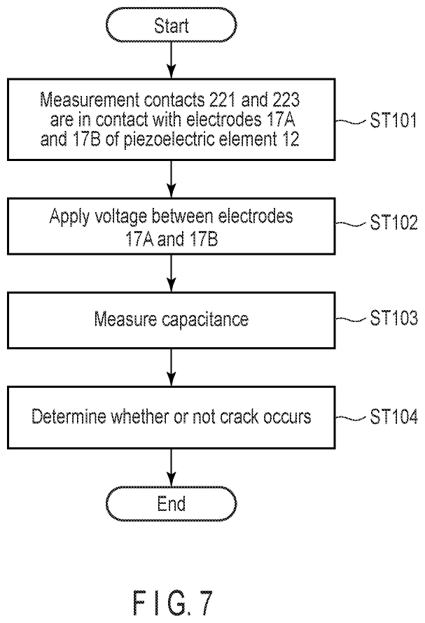

FIG. 7 is a flowchart showing an example of a process of inspecting the piezoelectric element 12 by the inspection device 200.

First, in step ST101, the measurement contacts 221 and 223 are brought into contact with the feed connection portions 171 of the electrodes 17A and 17B, respectively. Then, in step ST102, the measurement device 210 applies a voltage between the electrodes 17A and 17B via the measurement contacts 221 and 223.

Then, in step ST103, the measurement device 210 measures the capacitance. Finally, in step ST104, the determination module 231 of the control device 230 determines whether or not the piezoelectric element 12 has a crack, based on the measured capacitance.

For example, the determination module 231 determines that the piezoelectric element 12 has a crack if the measured capacitance does not fall within a range of a reference value, and the determination module 231 determines that the piezoelectric element 12 has no crack if the measured capacitance falls within the range of the reference value.

The reference value is stored in, for example, a storage device provided in advance in the control device 230. The determination result may be displayed on display means (not shown) such as a display provided on the inspection device 200.

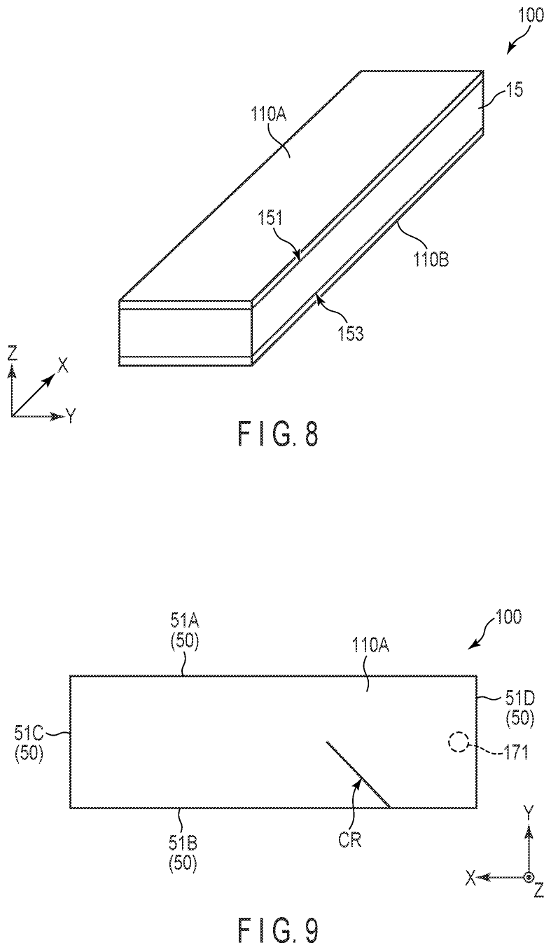

FIG. 8 is a schematic perspective view showing a piezoelectric element 100 according to a comparative example. The piezoelectric element 100 according to the comparative example comprises the piezoelectric body 15 and electrodes 110A and 110B. The electrode 110A is formed on the entire first main surface 151 of the piezoelectric body 15, and the electrode 110B is formed on the entire second main surface 153 of the piezoelectric body 15. Each of the electrodes 110A and 110B does not include slits.

FIG. 9 is a view illustrating a state in which a crack CR occurs in the piezoelectric element 100 according to the comparative example. A crack referred to as a microcrack or the like may occur in the piezoelectric element. The crack is likely to easily occur from one long side of the piezoelectric element to the other long side. In addition, the crack is formed only in the middle of the short side direction or the thickness direction of the piezoelectric element.

The piezoelectric element 100 according to the comparative example has a crack CR. The crack CR is a microcrack. The crack CR occurs on, for example, the electrode 110A and the piezoelectric body 15 on the side of the electrode 110A. The crack CR is formed, for example, from the edge 51B to the edge 51A. However, the cracks CR do not reach the edge 51A.

In the electrode 110A, an area between the edge 51D and the crack CR is electrically connected to an area between the edge 51C and the crack CR. In such a case, when a voltage is applied to the piezoelectric element 100, a current flows throughout the electrode 110A. For this reason, the capacitance of the piezoelectric element 100 hardly changes as compared to a case where the piezoelectric element 100 has no crack CR.

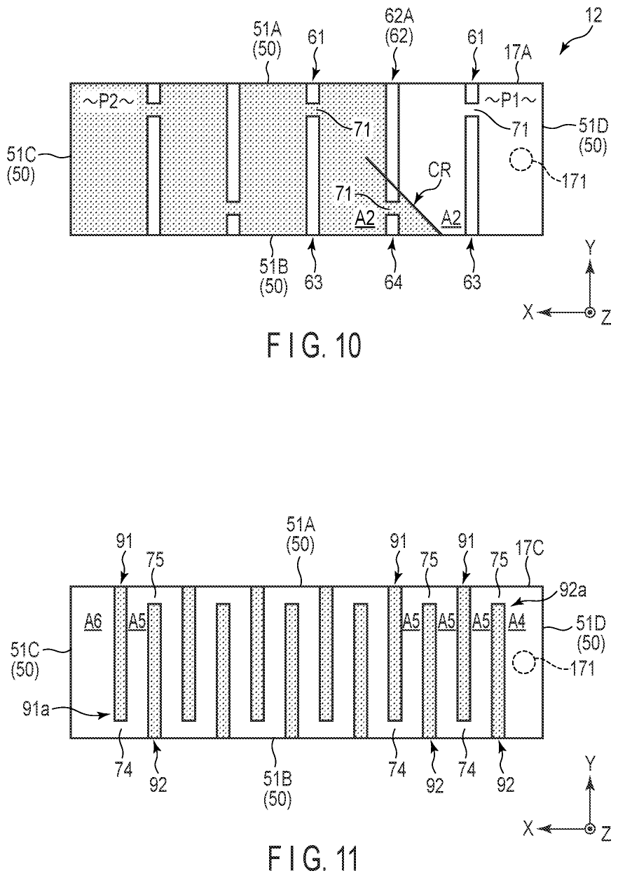

FIG. 10 is a view illustrating a state in which a crack CR occurs in the piezoelectric element 12 according to the present embodiment. The piezoelectric element 12 has a crack CR. The crack CR intersects with a slit (referred to as a slit 62A in FIG. 10) of the plurality of slits 61 to 64.

In this case, the electrode 17A has a conductive area P1 and a non-conductive area P2. In FIG. 10, the non-conductive area P2 is marked with dots. The non-conductive area P2 is not electrically connected to the conductive area P1 by the crack CR and the slit 62A.

More specifically, the areas A2 adjacent in the direction X are not electrically connected to each other by the crack CR and the slit 62A. In such a case, when a voltage is applied to the piezoelectric element 12, a current flows in the conductive area P1, but does not flow in the non-conductive area P2.

The area of the conductive area P1 is smaller than the area of the electrode 17A, in plan view. In other words, the part of electrode 17A that functions as the electrode surface is smaller. For this reason, the capacitance of the piezoelectric element 12 is smaller than that in the case where the piezoelectric element 12 has no crack CR.

As a result, in the process ST104 described with reference to FIG. 7, the determination module 231 of the control device 230 determines that the piezoelectric element 12 has the crack CR. As a result, the crack CR can be detected in the inspection process of the piezoelectric element 12.

The occurrence of the crack CR on the electrode 17A side has been described, but the steps are the same as those in a case where the crack CR occurs on the electrode 17B side.

The crack CR such as a microcrack can easily be detected by the piezoelectric elements 12 and 13 and the suspension 10 on which the piezoelectric elements 12 and 13 are mounted. More specifically, the electrode 17A of the piezoelectric element 12 includes a plurality of slits 61 to 64. The end portions 61a to 64a of the slits 61 to 64 are spaced apart from the peripheral edge 50.

A current flows through the entire electrode 17A before the crack CR occurs in the piezoelectric element 12 or 13. On the other hand, when the crack CR occurs in the piezoelectric element 12 or 13, the conductive area P1 (shown in FIG. 10) and the non-conductive area P2 (shown in FIG. 10) are formed in the electrode 17A by the crack CR and the slits 61 to 64. The area of the conductive area P1 is smaller than the entire area of the electrode 17A.

For this reason, the capacitance of the piezoelectric elements 12 and 13 is smaller than that before the crack CR occurs. In other words, the presence or absence of the crack CR can be detected as a change in capacitance, in the piezoelectric elements 12 and 13. As a result, the crack CR such as a microcrack can easily be detected in the present embodiment.

In the present embodiment, the electrode 17B has the same shape as the electrode 17A. Therefore, when the crack CR occurs on the electrode 17B side, the conductive area P1 and the non-conductive area P2 are also formed on the electrode 17B.

In the present embodiment, not only the crack CR occurring on the electrode 17A side, but the crack CR occurring on the electrode 17B side can be detected in the piezoelectric elements 12 and 13.

According to the present embodiment, the presence or absence of the crack CR is detected by not the appearance inspection such as image inspection or visual inspection, but the change in capacitance. Therefore, a crack CR occurring at a part that are hidden and not visible by image inspection or visual inspection can also be detected.

Furthermore, the crack CR such as a microcrack may be developed to a larger crack over a long period of time. According to the present embodiment, occurrence of a large crack can be suppressed by detecting the crack CR in the inspection process, and the piezoelectric elements 12 and 13 having a high reliability can be provided.

In the present embodiment, the crack CR can be detected by using the suspension 10 on which the piezoelectric elements 12 and 13 are mounted. Therefore, the crack CR occurring in the manufacturing process can be detected. The suspension 10 on which the piezoelectric elements 12 and 13 having a high reliability are mounted can be thereby provided.

In the present embodiment, the plurality of slits 61 and 62 extend from the edge 51A, and the plurality of slits 63 and 64 extend from the edge 51B.

The slits 61 are spaced apart from and arranged alternately with the slits 62, and the slits 63 are spaced apart from and arranged alternately with the slits 64, in the direction X.

As a result, even if the crack CR occurs from either of the edges 51A and 51B, the conductive area P1 and the non-conductive area P2 are likely to be formed in the electrode 17A. As a result, the detection accuracy of the crack CR can be improved in the present embodiment. In addition to the above-described effects, various desirable effects can be obtained from the present embodiment.

In the present embodiment, an example of detecting the crack CR by the change in capacitance is disclosed as an example of the change in electrical characteristics, but the crack CR may also be detected by the change in electrical characteristics other than the capacitance.

In the present embodiment, the slits 61 to 64 may be formed on only one of the electrodes 17A and 17B. The number of the plurality of slits 61 to 64 may be more or less than the number illustrated.

In the present embodiment, the shape of the electrodes is explained using the piezoelectric elements 12 and 13, but the shape can also be applied to the electrodes of the piezoelectric elements 14A and 14B mounted on the magnetic head side.

Next, other embodiments will be described. In each of the following embodiments, the shapes applicable to the electrodes will be described. In the other embodiments described below, the same constituent elements as those of the above-described first embodiment will be denoted by the same reference numerals as those of the first embodiment, and their detailed description may be omitted or simplified.

### Second Embodiment

FIG. 11 is a schematic plan view showing the electrode 17C according to the present embodiment. The electrode 17C includes a plurality of slits 91 and 92.

In the present embodiment, the slits 91 and 92 correspond to examples of the first slit. In FIG. 11, the plurality of slits 91, 92 are marked with dots.

The plurality of slits 91 and 92 penetrate the electrode 17C in the direction Z. The plurality of slits 91 extend from an edge 51A to an edge 51B, and the plurality of slits 92 extend from the edge 51B to the edge 51A. For example, the slits 91 and 92 are formed parallel to the Y-axis.

The slit 91 includes an end portion 91a and the slit 92 includes an end portion 92a. The end portions 91a and 92a are spaced apart from a peripheral edge 50. More specifically, the end portions 91a are separated from the edge 51B, and the end portions 92a are separated from the edge 51A. From the other viewpoint, the end portions 91a and 92a of the slits 91 and 92 do not open toward the peripheral edge 50.

A length of the slit 91 in the direction Y is equal to a length of the slit 92 in the direction Y. The length of the slits 91 and 92 in the direction Y is, for example, greater than half the length of the electrode 17C in the direction Y.

The slits 92 are spaced apart from and arranged alternately with the slits 91 in the direction X. For example, the slits 91 and the slits 92 are arranged at regular intervals in the direction X. The slits 92 are not aligned with the slits 91 in the direction Y.

The electrode 17C further includes a plurality of conductive portions 74 and 75. In the direction Y, the plurality of conductive portions 74 are located between the plurality of slits 91 and the edge 51B, and the plurality of conductive portions 75 are located between the plurality of slits 92 and the edge 51A.

An area A4 between an edge 51D and the slit 92 is electrically connected to areas A5 between the slits 91 and the slits 92 by the conductive portions 75. Similarly, the areas A5 adjacent in the direction X are electrically connected by the conductive portions 74 and 75.

Similarly, an area A6 between an edge 51C and the slit 91 is electrically connected to the areas A5 by the conductive portions 74. For example, the electrode 17C includes a feed connection portion 171 in the vicinity of the edge 51D.

The same advantages as those of the first embodiment described above can also be obtained in the configuration of the present embodiment.

### Third Embodiment

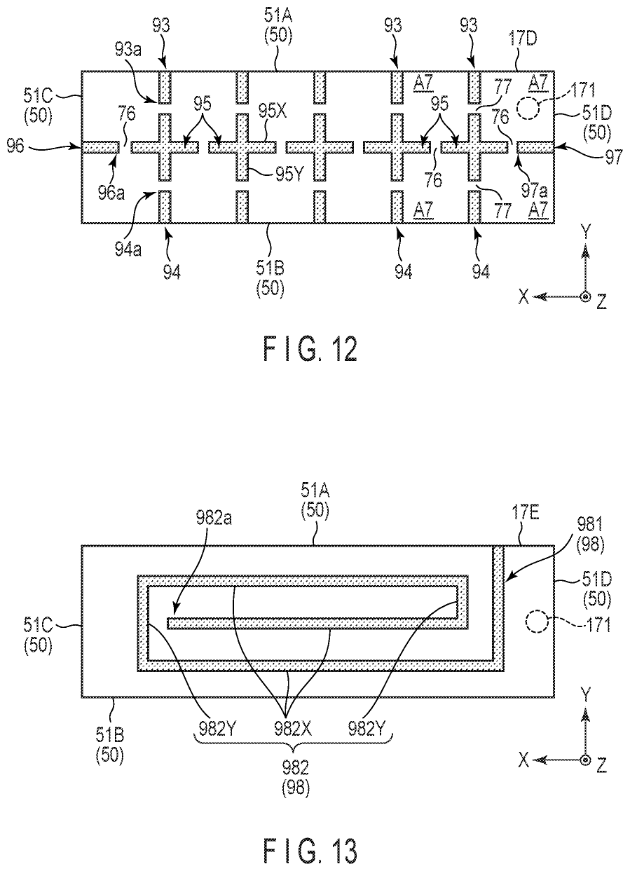

FIG. 12 is a schematic plan view showing an electrode 17D according to the present embodiment. The electrode 17D includes a plurality of slits 93 to 95 and slits 96 and 97. In the present embodiment, the slits 93, 94, 96, and 97 correspond to examples of the first slit. In FIG. 12, the slits 93 to 97 are marked with dots respectively.

The slits 93 to 97 penetrate the electrode 17D in the direction Z. The plurality of slits 93 extend from an edge 51A to an edge 51B, and the plurality of slits 94 extend from the edge 51B to the edge 51A. For example, the slits 93 and 94 are formed parallel to the Y-axis.

The slit 93 includes an end portion 93a and the slit 94 includes an end portion 94a. The end portions 93a and 94a are spaced apart from a peripheral edge 50. From the other viewpoint, the end portions 93a and 94a of the slits 93 and 94 do not open toward the peripheral edge 50. A length of the slit 93 in the direction Y is equal to a length of the slit 94 in the direction Y. For example, the plurality of slits 93 and 94 are arranged at regular intervals in the direction X.

The slit 96 extends from an edge 51C to an edge 51D, and the slit 97 extends from the edge 51D to the edge 51C. For example, the slits 96 and 97 are formed parallel to the X-axis. A length of the slit 96 in the direction X is equal to a length of the slit 97 in the direction X.

The slit 96 includes an end portion 96a and the slit 97 includes an end portion 97a. The end portions 96a and 97a are spaced apart from a peripheral edge 50. From the other viewpoint, the end portions 96a and 97a of the slits 96 and 97 do not open toward the peripheral edge 50.

The plurality of slits 95 are aligned in the direction Y. The slits 95 have, for example, a cross shape. The slit 95 includes a portion 95X extending in the direction X and a portion 95Y extending in the direction Y. The size of the portion 95X is equal to the size of the portion 95Y. The portion 95X is orthogonal, for example, in the center of the portion 95Y.

The slit 97, the portions 95X of the plurality of slits, and the slit 96 are aligned in this order in the direction X. The slit 94, the portions 95Y of the slit, and the slit 93 are aligned in this order in the direction Y.

The electrode 17D further includes a plurality of conductive portions 76 and 77. The conductive portions 76 are located between the slit 95 and the slit 96, between the slits 95, and between the slit 95 and the slit 97 in the direction X.

The conductive portions 77 are located between the slit 93 and the slit 95 and between the slit 94 and the slit 95 in the direction Y. An area A7 around the slits 95 is electrically connected by the conductive portions 76 and 77. For example, the electrode 17D includes a feed connection portion 171 in the vicinity of the edge 51D.

The same advantages as those of the above-described embodiments can also be obtained in the configuration of the present embodiment.

### Fourth Embodiment

FIG. 13 is a schematic plan view showing an electrode 17E according to the present embodiment. The electrode 17E includes a slit 98. In the present embodiment, the slit 98 corresponds to an example of the first slit. In FIG. 13, the slit 98 is marked with dots. The slit 98 penetrates the electrode 17E in the direction Z. The slit 98 has, for example, a spiral shape.

The slit 98 includes, for example, a slit portion 981 and a slit portion 982. The slit portion 981 extends from an edge 51A to an edge 51B. The slit portion 981 does not reach the edge 51B. For example, the slit portion 981 is formed parallel to the Y-axis.

The length of the slit portion 981 in the direction Y is larger than, for example, half the length of the electrode 17E in the direction Y.

The slit portion 982 is connected with the slit portion 981. The slit portion 982 includes an end portion 982a. The end portion 982a corresponds to an end portion of the slit 98. The end portion 982a is separated from a peripheral edge 50. From the other viewpoint, the slit 98 does not open toward the peripheral edge 50.

The slit portion 982 includes a plurality of portions 982X extending in the direction X and a plurality of portion 982Y extending in the direction Y.

The portions 982X and 982Y are connected alternately, and the slit portion 982 is thereby formed.

As shown in FIG. 13, the electrode 17E does not include an area where no current flows, due to the slit 98. In other words, the area which is not electrically connected to other areas, is not formed in the electrode 17E, due to the slit 98. For example, the electrode 17E includes a feed connection portion 171 between the slit portion 981 and an edge 51D.

The same advantages as those of the above-described embodiments can also be obtained in the configuration of the present embodiment. Incidentally, the slit portion 981 of the slit 98 extends from the edge 51A, but the slit portion 981 may extend from one of the edges 51B to 51D.

### Fifth Embodiment

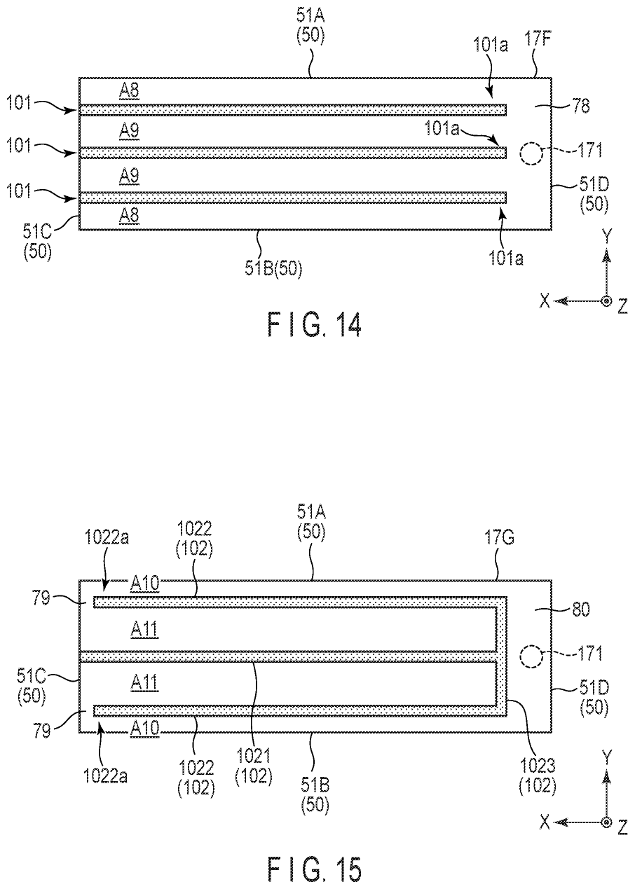

FIG. 14 is a schematic plan view showing an electrode 17F according to the present embodiment. The electrode 17F includes a plurality of (for example, three) slits 101. In the present embodiment, the slit 101 corresponds to an example of the first slit. In FIG. 14, the plurality of slits 101 are marked with dots.

The plurality of slits 101 penetrate the electrode 17F in the direction Z. The plurality of slits 101 extend from an edge 51C to an edge 51D. For example, the slits 101 are formed parallel to the X-axis.

The slits 101 include end portions 101a. The end portions 101a are spaced apart from a peripheral edge 50. More specifically, the end portions 101a are spaced apart from the edge 51D. From the other viewpoint, the end portions 101a of the slits 101 do not open toward the peripheral edge 50.

For example, the plurality of slits 101 are arranged at regular intervals in the direction Y, but are not limited to this example. The length of the slits 101 in the direction X is, for example, greater than half the length of the electrode 17F in the direction X.

The electrode 17F includes a conductive portion 78. The conductive portion 78 is located between the end portions 101a of the plurality of slits 101 and the edge 51D.

Areas A8 between edges 51A and 51B and the slits 101 are electrically connected to areas A9 between the slits 101 by the conductive portion 78. Similarly, the areas A9 adjacent in the direction Y are electrically connected by the conductive portion 78. For example, the electrode 17F includes a feed connection portion 171 in the vicinity of the edge 51D.

The same advantages as those of the above-described embodiments can also be obtained in the configuration of the present embodiment. Incidentally, the number of slits 101 is not limited to three, but may be two or less, or four or more.

### Sixth Embodiment

FIG. 15 is a schematic plan view showing an electrode 17G according to the present embodiment. The electrode 17G includes a slit 102. In the present embodiment, the slit 102 corresponds to an example of the first slit. In FIG. 15, the slit 102 is marked with dots. The slit 102 penetrates the electrode 17G in the direction Z.

The slit 102 includes, for example, a slit portion 1021, a pair of slit portions 1022, and a slit portion 1023. In the present embodiment, the slit portion 1021 corresponds to an example of a first slit portion and the slit portions 1022 correspond to examples of a second slit portion.

The slit portion 1021 extends from an edge 51C to an edge 51D. The slit portion 1021 is located between the pair of slit portions 1022 in the direction Y. The slit portions 1022 are spaced apart from and aligned with the slit portions 1021.

The pair of slit portions 1022 extend along the slit portion 1021. For example, the slit portion 1021 and the pair of slit portions 1022 are formed parallel to the X-axis. The length of the slit portions 1021 and 1022 in the direction X is, for example, greater than half the length of the electrode 17G in the direction X. The length of the pair of slit portions 1022 in the direction X is smaller than the length of the slit portion 1021 in the direction X.

The slit portion 1023 extends in the direction Y. The length of the slit portion 1023 in the direction Y is, for example, greater than half the length of the electrode 17G in the direction Y. The pair of slit portions 1022 are connected with the slit portion 1021 via the slit portion 1023. For example, the pair of slit portions 1022 are connected to both end portions of the slit portion 1023, respectively, and the slit portion 1021 is connected to a center portion of the slit portion 1023.

The pair of slit portions 1022 have end portions 1022a, respectively. The end portions 1022a correspond to the end portions of the slit 102. The ends 1022a are spaced apart from a peripheral edge 50. More specifically, the end portions 1022a are spaced apart from the edge 51C. From the other viewpoint, the end portions 1022a of the slit portions 1022 do not open toward the peripheral edge 50.

The electrode 17G further includes two conductive portions 79 and a conductive portion 80. The conductive portions 79 are located between the pair of slits 1022 and the edge 51C. The conductive portion 80 is located between the slit portions 1023 and the edge 51D.

Areas A10 between edges 51A and 51B and the slit portions 1022 are electrically connected to areas A11 between the slit portion 1021 and the slit portions 1022 by the conductive portion 79. The area A10 between the edge 51A and the slit portion 1022 is electrically connected to the area A10 between the edge 51B and the slit portion 1022 by the conductive portion 80. For example, the electrode 17G includes a feed connection portion 171 in the vicinity of the edge 51D.

The same advantages as those of the above-described embodiments can also be obtained in the configuration of the present embodiment. In the present embodiment, the slit 102 includes the slit portion 1021 and a pair of slit portions 1022 extending along the slit portion 1021.

For example, if a crack CR occurs from the edge 51A, the crack CR intersects the slit portion 1022 on the edge 51A side. As a result, electricity will not flow to the area A11 on the edge 51A side, and the area of the non-conductive area P2 can be increased. In other words, the change in capacitance when a crack CR occurs is increased. As a result, the detection accuracy of the crack CR can be improved.

In implementing the invention disclosed in the above embodiments, the specific aspect of each element constituting the disk drive suspension can be variously changed, including the specific aspect of shapes of the base plate, load beam, flexure, and the like.

Various aspects of the invention can also be extracted from any appropriate combination of constituent elements disclosed in the embodiments. Some constituent elements may be deleted in all of the constituent elements disclosed in the embodiments. The constituent elements described in different embodiments may be combined arbitrarily.

For example, the two electrodes provided in the piezoelectric element may have different shapes. More specifically, each of the two electrodes may include each of the above-described embodiments. In this case, the width of the slits is desirably sufficiently small. When the suspension comprises a plurality of piezoelectric elements, for example, the shape of the electrodes provided at the piezoelectric elements may be different, depending on the location on which the piezoelectric elements are mounted.

In each of the above-described embodiments, each of the slits is formed by the portion extending in the direction X and the portion extending in the direction Y, but the slit may include a portion extending in a direction intersecting the directions X and Y or may include a curved portion.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A piezoelectric element comprising:
a piezoelectric body having a first main surface and a second main surface located on a side opposite to the first main surface;
a first electrode provided on the first main surface; and
a second electrode provided on the second main surface, wherein
the first electrode includes a first peripheral edge and a first slit extending from the first peripheral edge, and
an end portion of the first slit is separated from the first peripheral edge.

2. The piezoelectric element of claim 1, wherein
a plurality of first slits are provided along the first peripheral edge.

3. The piezoelectric element of claim 2, wherein
the first peripheral edge includes a first edge portion extending in a first direction, and a second edge portion extending in the first direction and aligned with the first edge portion in a second direction that intersects the first direction, and
the first slits extending from the first edge portion are spaced apart from the first slits extending from the second edge portion, in the second direction.

4. The piezoelectric element of claim 2, wherein
the first peripheral edge includes a first edge portion extending in a first direction, and a second edge portion extending in the first direction and aligned with the first edge portion in a second direction that intersects the first direction, and
the first slits extending from the first edge portion are spaced apart from and arranged alternately with the first slits extending from the second edge portion, in the second direction.

5. The piezoelectric element of claim 1, wherein
the first slit has a spiral shape.

6. The piezoelectric element of claim 1, wherein
the first slit includes a first slit portion extending from the first peripheral edge, and a pair of second slit portions connected to the first slit portion,
the first slit portion is located between the pair of second slit portions,
the pair of second slit portions extend along the first slit portion, and
each of end portions of the pair of second slit portions is separated from the first peripheral edge.

7. A piezoelectric element comprising:
a piezoelectric body having a first main surface and a second main surface located on a side opposite to the first main surface;
a first electrode provided on the first main surface; and
a second electrode provided on the second main surface, wherein
the first electrode includes a first peripheral edge and a first slit extending from the first peripheral edge,
the second electrode includes a second peripheral edge and a second slit extending from the second peripheral edge,
an end portion of the first slit is separated from the first peripheral edge, and
an end portion of the first slit is separated from the first peripheral edge.

8. A disk drive suspension comprising the piezoelectric element of claim 1.

9. A disk drive suspension comprising the piezoelectric element of claim 7.
